(19) United States
(12) Patent Application Publication
(10) Pub. No.: US 2025/0031343 A1
(43) Pub. Date: Jan. 23, 2025

(54) ELECTRONIC ENCLOSURE WITH IMPROVED HEAT TRANSFER PERFORMANCE

(71) Applicant: Eagle Technology, LLC, Melbourne, FL (US)

(72) Inventors: Clarke O. Fowler, Merritt Island, FL (US); Voi Van Nguyen, Oviedo, FL (US)

(21) Appl. No.: 18/356,826

(22) Filed: Jul. 21, 2023

(51) Int. Cl. H05K 7/20

(52) U.S. Cl. CPC H05K 7/20263

(57) ABSTRACT

An electronic enclosure having improved cooling capacity using a radial fin pattern that is fabricated using additive manufacturing methods is disclosed.

### TECHNICAL FIELD

The present invention relates to the field of heat transfer, and more particularly, to curved offset fin devices used within a fluid flow path within a heat exchanger that is in a liquid cooled electronics chassis.

### BACKGROUND

Electronic chassis assemblies which include multiple circuit modules mounted in a chassis are widely used in electronic applications. An electronic chassis assembly may include a chassis configured to mechanically support the circuit modules, electrical connectors to interconnect the circuit modules, power supplies for operation of the circuit modules and one or more external connectors to connect the circuit module assembly to external equipment. The electronic chassis assemblies are widely used in military and aircraft applications but are not limited to such applications. Circuit module chassis assemblies for military applications must be designed to operate reliably in harsh environments.

The electronics chassis assemblies typically require a cooling system to remove heat generated by the circuit components and to maintain the circuit modules within a specified temperature range. Various cooling techniques are utilized, including conduction cooling, air-flow-through cooling and liquid-flow-through cooling. By way of example, conduction cooling may be used up to 70 watts heat generation, air-flow-through cooling may be used up to 250 watts heat generation, and liquid-flow-through cooling may be used up to 1000 watts heat generation. The trend is toward circuit modules which have higher speed and higher performance, but which generate larger amounts of heat.

Many liquid-flow-through heat exchangers in use today employ one or more rows of so-called flattened tubes which extend between headers provided with tanks or even tubular headers. External fins are bonded to the exterior of the flattened tubes and in some instances, internal fins within the tubes are utilized. Such fins increase surface area within the tubes and provide a means whereby heat may flow from the fluid flowing within the tubes to the insert and then to the walls of the tube through the insert. Thus, where the insert is a better conductor of heat than the fluid flowing within the tube, enhanced heat transfer results.

In addition, such inserts may provide a turbulating function. That is to say, they increase turbulence in the fluid flowing within the tube which in turn is known to increase heat transfer efficiency.

Moreover, where such tubes are to carry fluid at a relatively high pressure and are not supported by the external fins, the inserts, being bonded to both side walls, strengthen the tubes as well.

Techniques for constructing such heat exchangers include vacuum brazing. Brazing may be performed, for example, in a molten salt bath or in a vacuum furnace and requires very high temperatures (from 300° C. to 1100° C.). These high temperatures melt a brazing material, such as metals or compatible alloys (e.g. aluminum alloys), that is in contact with two or more other pieces of metal that are part of the heat exchanger. Upon cooling, the brazing material solidifies, forming a bond that thermally, and physically, couples the metal pieces together. The high temperature needed for brazing places limits on the heat exchangers being constructed. For example, the material used to make the heat exchanger must have a melting point higher than the brazing temperature. Moreover, the large temperature variation, from room temperature to the brazing temperature and back, require the materials that are chosen to have similar coefficients of thermal expansion (CTE). If the heat exchanger was constructed from metal with a large difference in CTE, the heat exchanger could break, warp or have unwanted residual stress upon cooling to room temperature. Limitations are also put on the choice of material based on the need to reduce galvanic corrosion.

Another restriction of brazing is that it typically requires special equipment, such as a molten salt bath or a vacuum furnace. Therefore, the brazing process requires purchasing expensive, specialized equipment or contracting an off-site brazing specialist, which can be both unaffordable and time-consuming, with lead times of greater than 16 weeks.

This invention is directed to overcoming one or more of the above problems.

### BRIEF DESCRIPTION OF THE DRAWINGS

FIG. 1 is an isometric view of an electronic chassis in accordance with the prior art.

FIG. 2 is an isometric view of an example of lanced and offset fins used for heat transfer of an electronic chassis.

FIG. 3A is an isometric view of an electronic chassis in accordance with an exemplary embodiment of the invention.

FIG. 3B is a close-up isometric view of a section of lanced and offset fins in accordance with an exemplary embodiment of the invention.

FIG. 4 is a top plan view showing the curved lanced and offset fins in accordance with an exemplary embodiment of the invention.

### DETAILED DESCRIPTION OF THE EMBODIMENTS

The present description is made with reference to the accompanying drawings, in which exemplary embodiments are shown. However, many different embodiments may be used, and thus the description should not be construed as limited to the particular embodiments set forth herein. Rather, these embodiments are provided so that this disclosure will be thorough and complete. Like numbers refer to like elements throughout.

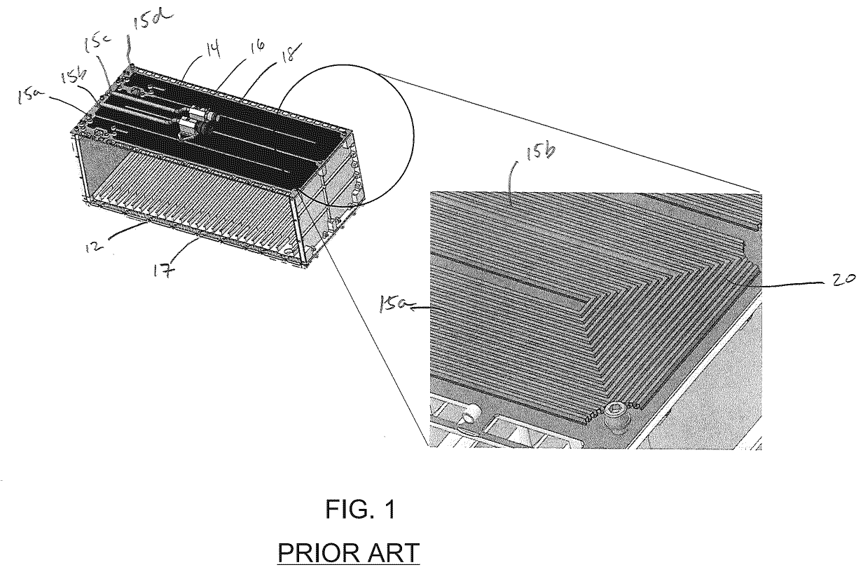

Referring initially to FIG. 1, an electronic enclosure 12 in accordance with the prior art is shown. The electronic enclosure 12 is configured to house and retain a plurality of electronic cards in slots 17 arranged along the top and bottom surface of the electronic enclosure 12. Disposed on a top external surface of the enclosure 12 is a liquid cooled heat exchanger 14. The liquid cooled heat exchanger 14 is comprised of a fluid inlet 16 and a fluid outlet 18. The heat exchanger 14 also comprises a plurality of passageways 15a, 15b, 15c and 15d such that cooling fluid is transferred in a serpentine pattern through the heat exchanger 14. Heat therefore from the electronic cards is thereby transferred to the cooling fluid as it travels from the fluid inlet 16 to the fluid outlet 18.

Disposed in the heat exchanger 14 is a predetermined arrangement of lanced offset fin stock 20 that is configured to improve the transfer of heat energy from the electronic enclosure 12 to the cooling fluid. As the cooling fluid travels through the passageways 15a, 15b, 15c and 15d, it must make a 180 degree change in direction when it reaches the end of the electronic enclosure 12. In the prior art, this change in direction is typically accomplished by 90-degree mitered corners as shown in the figure. This somewhat abrupt change in the direction of the flow of the cooling fluid is known to severely impact the efficiency of the heat exchanger.

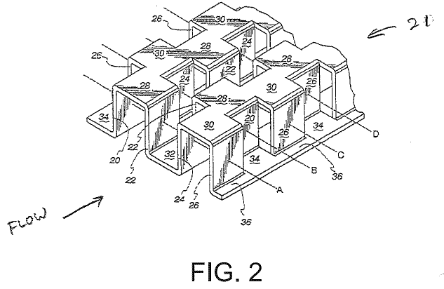

Referring now to FIG. 2, which shows a detailed isometric view of the lanced and offset fin stock 20 that is currently used in prior art heat exchangers.

While inserts of the sort have taken on many forms, a so-called “lanced and offset” fin 20 is preferred in many applications. The heat exchanger art is beginning to recognize that lanced and offset fins are “the” internal fin for use in fluid heat exchangers because of their ability to perform in many instances with greater efficacy, than more standard internal fin configurations.

In particular, heretofore, lanced and offset fins have been produced by what the art refers to as stitching machines. In the operation of such machines, the dies that produce the lanced and offset configuration of the fin move forward and back and from side to side. The fin formed has a flow path that extends in the direction across the stitching machine. Thus, the length of the fin is limited to the maximum operative width of the stitching machine. As a consequence, and dependent upon the length of the heat exchanger that are to be provided with such lanced and offset fins, it may be necessary to insert the lanced and offset fin as more than one piece in order to extend for the full length of the heat exchanger. Unfortunately, this takes plural insertion operations which are time consuming and when more than one fin piece is inserted, there is a possibility that there will be a gap between the insert pieces. At such a location, there will be no insert to bond to the interior sides of the heat exchanger and as a consequence, there will be a location that is not provided with enhanced strength by the presence of an insert bonded thereto. Consequently, the possibility of failure when subject to high pressure is enhanced.

Furthermore, the very nature of the stitching machine operation is such that it is a very, very slow production method. Typically, for a length equal to the maximum operative length of the stitching machine, the stitching machine can only produce one leg of a lanced and offset fin during each second of operation. Thus, a fin having six legs would require six seconds to manufacture.

Referring again to FIG. 2, a four legged lanced and offset fin 21 is illustrated. A first leg is shown at 20 while a second leg is shown at 22. A third leg is shown at 24 while a fourth is shown at 26. The legs 20 and 22 are connected at their upper ends by a peak or crest 28. A similar crest or peak 30 connects the upper ends of the legs 24, 26. The lower ends of the legs 22, 24 are connected by a lower crest or peak 32. A partial crest or peak 34 extends from the lower end of the leg 20 in a direction away from the leg 22 while a smaller partial crest or peak 36 extends from the lower end of the leg 26 away from the leg 24. These components form a first row A of legs and crests that generally extends transversely of the direction of elongation of the fin which is from lower left to upper right as illustrated in FIG. 1. A second row B of legs and crests is immediately behind and connected to the row A in a fashion well known. The row B is a reversal of the row A which is to say that the leg 26 appears on the left as viewed in FIG. 1 while the leg 20 appears on the right as viewed in FIG. 1.

A third row C is identical to the row A while the next row D is identical to the row B. These rows alternate from one end of the strip to the other in the above-described fashion.

It will be noted that the arrangement is such that the leg 20 of the row A is located midway between the legs 24, 26 of the row B; the leg 22 of the row A is located midway between the legs 22, 24 of the row B; the leg 24 of the row A is located midway between the legs 22, 20 of the row B and the leg 26 of the row A is located to one side of the leg 20 of row B a distance approximately equal to half the distance between any two adjacent legs in a given row. The resulting configuration is that shown in FIG. 2. In the same fashion, the crests 28, 30 are staggered, between adjacent rows A, B, C, D, etc., although they are connected over approximately half their length to the adjacent crests as can be seen in FIG. 2.

In an exemplary embodiment of the invention, the lanced and offset fin 21 may be made from 300 series aluminum alloy with a uniform thickness of 0.006″-0.010″. The fin height, thickness, offset length and resulting pressure drop can all be modified to arrive at a desired performance for a given application.

In order to fabricate a heat exchanger 14 that incorporates the lanced and offset fin technology as shown in FIGS. 1 and 2, the various components such as the top plate, bottom plate, and the lanced and offset fins are clad with a filler alloy or brazing material which allows for the joining of the various pieces into a unitary piece. The individual heat exchanger components are then assembled by a so-called core builder machine. This process can be manual or fully automated in operation. After assembly, a clamp or fixture or loading device is usually put on to the assembled heat exchanger components to hold the various components together, and the fixtured heat exchanger core assembly is then transferred to a brazing furnace.

The brazing is done typically at a temperature range of 530° C. to 615° C., more typically at a temperature range of 570° C. to 610° C., e.g. at about 580° C. or about 600° C. Further, brazing is preferably done for a period long enough for melting, wetting and spreading of any brazing material or filler metal present on the heat exchanger components to join the various heat exchanger components.

Accordingly, the brazing process step is combined with the heat exchanger core building process steps. The heat exchanger components are first assembled in a core builder machine, by for example methods known in the art. At least some of the components are at least partially covered with a filler metal such as a filler alloy, a filler metal generating flux compound, or other brazing material, which is intended to melt, wet and spread upon brazing to join the heat exchanger components together. For example, at least some of the components are manufactured from aluminium alloy brazing sheet, which is clad on at least one surface with a clad layer made from filler alloy or coated with a substance to generate filler metal with temperature, or from extruded products, such as tubes, which may also be clad with a filler alloy or coated with a substance to generate filler metal with temperature. As the reader can see, the vacuum brazing method of fabricating the heat exchanger is quite complex which has long lead times and is prone to quality control problems which affects yield issues.

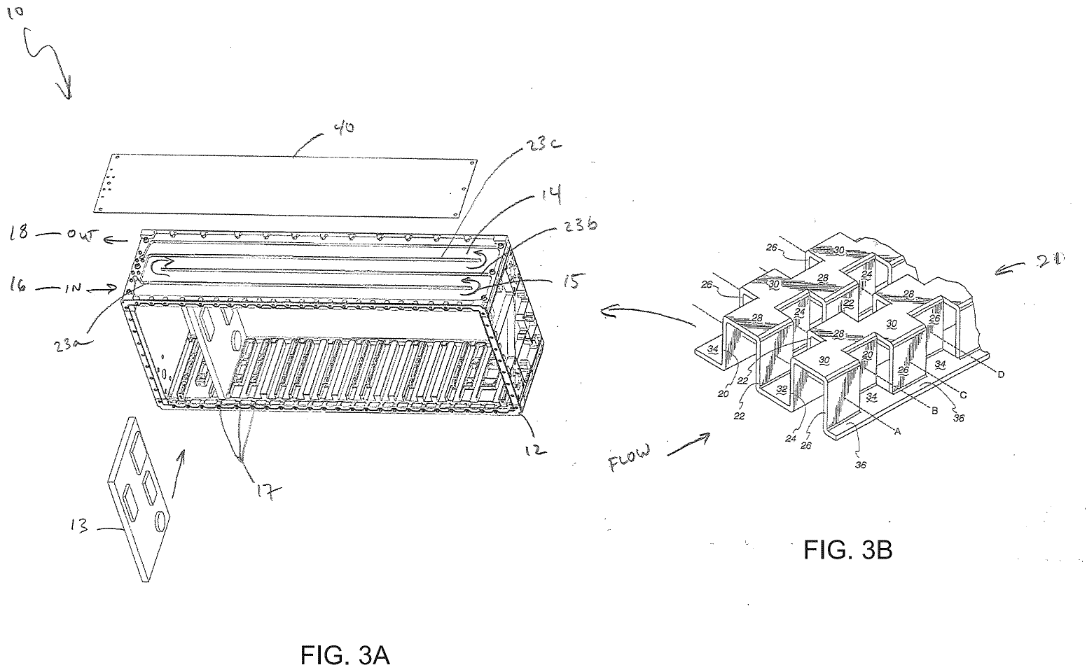

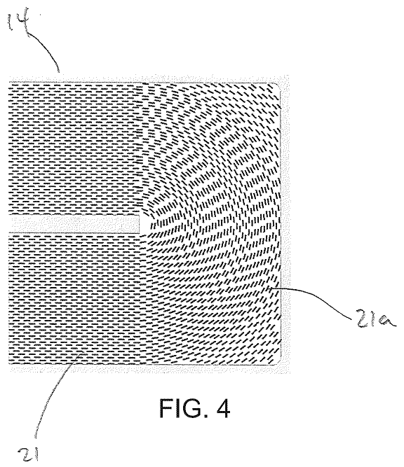

Referring now to FIGS. 3, 3A and 4, where like numerals indicate like features, an exemplary embodiment of the invention is shown. A liquid cooled electronics chassis 10 is comprised of an electronic enclosure 12 that is configured to removable accept and retain a plurality of electronic circuit cards 13 in slots 17 that are disposed internal to the electronic enclosure 12. The circuit cards 13 are configured to transfer the heat generated by the electronic components to the liquid cooled heat exchanger 14 as described previously.

In an exemplary embodiment of the invention, the heat exchanger 14 is comprised of a bottom plate 19 and a top plate 40 that is offset from the bottom plate 19 such that it creates a volume for the transfer of a cooling fluid therebetween. A plurality of passageways 15 are created internal to the heat exchanger 14 by walls 23a, 23b and 23c such that the cooling fluid traverses the heat exchanger 14 from a fluid inlet 16 to a fluid outlet 18 in a multipass pattern. In one embodiment, the cooling fluid may be comprised of liquid Polyalphaolefin (PAO). As described previously, at the end of each passageway, the cooling fluid must make two 90-degree turns. Disposed internal to the heat exchanger 14 at each of the 90-degree turns is a pattern of lanced and offset fin 21a that has been fabricated using additive manufacturing techniques to create a continuous radius thereby eliminating the need for the cooling fluid to make abrupt and inefficient 90-degree turns as it flows from the inlet to the outlet. The use of additive manufacturing techniques to fabricate the lanced and offset fin geometry along a radial path significantly enhances the heat transfer capability of the heat exchanger 14.

It will accordingly be appreciated that the use of additive manufacturing techniques will also allow for the creation of a lanced and offset fin geometry that is not necessarily of constant cross section and the design and placement of the individual fins of the lanced and offset fin can be tweaked to arrive at an optimal design for a given application.

Many modifications and other embodiments will come to the mind of one skilled in the art having the benefit of the teachings presented in the foregoing descriptions and the associated drawings. Therefore, it is understood that the disclosure is not to be limited to the specific embodiments disclosed, and that modifications and embodiments are intended to be included within the scope of the appended claims.

That which is claimed is:

1. An electronics enclosure comprising:
a housing configured to removably retain a plurality of electronic circuit cards;
a liquid cooled heat exchanger having an inlet and an outlet for the transmission of a cooling liquid from said inlet to said outlet, said heat exchanger disposed adjacent said housing in thermal communication with said circuit cards;
at least one wall disposed in said heat exchanger configured to create a multipass flow pattern of said cooling fluid as it travels from said inlet to said outlet; and,
a predetermined pattern of heat transfer fins disposed in said heat exchanger, said fins arranged in a radial pattern around each corner of the multipass flow pattern.

2. The electronics enclosure of claim 1, wherein said heat transfer fins are comprised of a lanced and offset fin geometry.

3. The electronics enclosure of claim 1, wherein said heat transfer fins are fabricated using an additive manufacturing process.

4. The electronics enclosure of claim 1, wherein said cooling fluid is comprised of a liquid Polyalphaolefin (PAO).

5. The electronics enclosure of claim 1, wherein said enclosure is disposed in an aircraft.

6. A heat exchanger comprising:
a fluid inlet in fluid communication with a fluid outlet;
a cooling fluid configured for transmission along a flow path from said fluid inlet to said fluid outlet;
a plurality of heat transfer fins disposed between said fluid inlet and said fluid outlet, wherein said fins are arranged in a radial pattern where there is a change in direction of said flow path.

7. The heat exchanger of claim 6, wherein said heat transfer fins are comprised of a lanced and offset fin geometry.

8. The heat exchanger of claim 7, wherein said heat transfer fins are fabricated using an additive manufacturing process.

9. The heat exchanger of claim 8, wherein said cooling fluid is comprised of a liquid Polyalphaolefin (PAO).

10. The heat exchanger of claim 9, wherein said heat exchanger is disposed in an aircraft.
